(19) United States
(12) Patent Application Publication
(10) Pub. No.: US 2026/0177936 A1
(43) Pub. Date: Jun. 25, 2026

(54) DEVICE AND METHOD FOR TREATING THE SURFACE OF AN OPTICAL ELEMENT OF A LITHOGRAPHY SYSTEM IN AN ATOMIC LAYER DEPOSITON PROCESS OR AN ATOMIC LAYER ETCHING PROCESS

(71) Applicant: Carl Zeiss SMT GmbH, Oberkochen (DE)

(72) Inventors: Freddy ROOZEBOOM, Waalre (NL); Alfredo MAMELI, Eindhoven (NL); Joop VAN DEELEN, Eindhoven (NL); Dirk EHM, Beckingen (DE)

(21) Appl. No.: 18/987,578

(22) Filed: Dec. 19, 2024

Related U.S. Application Data
(63) Continuation of application No. PCT/EP2023/066572, filed on Jun. 20, 2023.

(30) Foreign Application Priority Data
Jun. 20, 2022 (DE) 10 2022 206 124.1

(51) Int. Cl. G03F 7/00; C23C 16/455; C23C 16/458; C23C 16/50

(52) U.S. Cl. CPC G03F 7/70975; C23C 16/45544; C23C 16/4583; C23C 16/50; G03F 7/702; G03F 7/70233; G03F 7/7085; G03F 7/70891; G03F 7/70925; G03F 7/70933

(57) ABSTRACT

An optical element surface treating device for a lithography system performs an atomic layer treatment process and includes: a sample holder holding the optical element; a treatment head (120) with a first outlet (121) supplying a first precursor fluid (PF1) to a treatment region (102A) on the surface of the optical element, a cleaning assembly (123) removing excess first precursor fluid from the treatment region, and a second outlet (122) supplying a second precursor fluid (PF2) into the treatment region, wherein the first precursor fluid and the second precursor fluid provide an atomic layer deposition or etching process in the treatment region, and the first or the second precursor fluid is a liquid: and a movement unit (130) moving the treatment head relative to the sample holder with the optical element. The first outlet, the cleaning assembly, and the second outlet are guided one by one over the treatment region.

### CROSS REFERENCE TO RELATED APPLICATIONS

This is a Continuation of International Application PCT/EP2023/066572, which has an international filing date of Jun. 20, 2023, and which claims the priority of German Patent Application 10 2022 206 124.1, filed Jun. 20, 2022. The disclosures of both applications are incorporated in their respective entireties into the present Continuation by reference.

### FIELD OF THE INVENTION

The present invention relates to an apparatus for processing a surface of an optical element of a lithography apparatus, especially an EUV lithography apparatus, in an atomic layer processing operation, and to a corresponding method. The invention further relates to a method of repairing a lithography apparatus.

### BACKGROUND

Microlithography is used to produce microstructured component parts, for example integrated circuits. The microlithography process is carried out using a lithography apparatus comprising an illumination system and a projection system. The image of a mask (reticle) illuminated by the illumination system is projected by the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV (extreme ultraviolet) lithography apparatuses that use light with a wavelength in the range from 0.1 nm to 30 nm, in particular 13.5 nm, are currently under development. Since most materials absorb light of this wavelength, it is necessary in such EUV lithography apparatuses to use reflective optics, i.e. mirrors, instead of-as previously-refractive optics, i.e. lens elements. Examples of mirrors used include those known as Bragg mirrors, which are formed from alternating layers of two materials having a different refractive index for the radiation to be reflected. For EUV radiation, for example, silicon and molybdenum has been found to be a suitable material pair. In order to prevent oxidation of the outer layer, which would worsen the optical properties of the mirror, a protective layer is frequently applied. Ruthenium, for example, is used therefor.

EUV radiation is generated, for example, by incidence of laser light on droplets of tin, creating a tin plasma that has an emission at 13.5 nm. In this process, however, tin from the radiation source can also get into the radiation forming device and the projection optics, where it can be deposited on optical surfaces or even the lithography mask. This contamination can impair the optical properties and hence the performance of the overall system. Therefore, after a particular period of operation of the lithography apparatus, for example, there is a need for a service in which the surfaces affected are cleaned. Tin can also form alloys, particularly with ruthenium, which are not easy to remove from the surface, which makes the cleaning process complex.

Furthermore, EUV radiation is conducted in a vacuum in EUV lithography apparatuses, since the absorption of the radiation by gas molecules at standard pressure is already too high. In this case, for example, molecular hydrogen is used as purge gas in the vacuum region of the EUV lithography apparatus. The hydrogen molecules are dissociated or ionized by the EUV radiation. The resultant hydrogen radicals or hydrogen ions are highly reactive. In particular, these can react with the tin deposits, forming volatile compounds and hence removing the tin. However, the hydrogen radicals can also react with and corrode other surfaces in the EUV lithography apparatus. Moreover, the volatile compounds thus formed can be deposited again elsewhere, for example on optical surfaces of the lithography apparatus, and contaminate these, which can worsen the optical properties thereof.

Atomic layer deposition (ALD) and atomic layer etching (ALE) are known methods that enable processing limited to a few atomic layers on the surface of an article. This is because of the self-limiting chemical reaction utilized in the methods, which affects only the uppermost layer of any surface. The methods are based on the formation of an adsorbed monolayer of a precursor on the surface, by exposing the surface to an atmosphere of the precursor in a first step. In ALE processes, the precursor can react chemically with atoms or molecules on the surface, for example by oxidation or reduction. The precursor is then pumped out of the atmosphere again, leaving only the adsorbed monolayer on the surface. In a second step, the monolayer formed is “activated”, by contacting it with a second precursor. The second precursor may comprise a high-energy species, such as free radicals, ions or photons, or else be chemically highly reactive with the first precursor or the monolayer formed. The reaction of the second precursor with the monolayer of the first precursor can result either in deposition of a monolayer of new material (deposition process), or else in breakdown of the monolayer and possible removal (etching process). The second precursor does not react automatically with the (untreated) surface, and therefore the reaction is limited to the monolayer. By repetition of the above-described steps, it is possible to deposit or remove a greater layer thickness.

In order to remove contamination on the optical surfaces, DE 10 2017 211 539 A1 discloses a method based on an atomic layer etching process. The process proposed can be performed simultaneously in a reactor for the entire surface, or else a processing head is used, which spatially separates the regions being processed and then “scans” the surface. In a first region of the processing head, in one section of the surface, the first part of the process is conducted, such that the monolayer is formed there. In a second region of the processing head, which is run across the section already covered by the first region, the second part of the process is conducted.

US 2016/0090652 A1 discloses an atomic layer deposition method in which liquid precursors are used, where the precursors are spin-coated onto the substrate. The substrate is disposed on a rotatable sample holder, and the sample holder with the substrate is rotated. The first liquid precursor is applied, with acceleration (spinning) of the precursor outward (in radial direction) owing to the rotation of the substrate and the inertia of the liquid. The spinning action means that no excess material remains on the surface. All that remains is the material adsorbed on the surface, which forms a monolayer. The same procedure is followed with the second, likewise liquid precursor. A chemical reaction between the first and second precursors is limited to the monolayer of the first precursor, and therefore the steps described each result in deposition of one monolayer of material. Higher layer thicknesses can be achieved by repetition of the steps mentioned.

### SUMMARY

Against this background, it is an object of the present invention to provide an improved apparatus for processing of a surface of an optical element of a lithography apparatus, and a corresponding method.

In a first aspect, an apparatus for processing a surface of an optical element of a lithography apparatus, especially an EUV lithography apparatus, in an atomic layer processing operation is proposed. The apparatus comprises a sample holder to hold the optical element during the processing operation, a processing head having a first outlet for supply of a first precursor fluid to a processing region on the surface of the optical element, a cleaning arrangement for removal of excess precursor fluid from the processing region, and a second outlet for supply of a second precursor fluid to the processing region, wherein the first precursor fluid and the second precursor fluid are selected in order to perform an atomic layer deposition process or an atomic layer etching process in the processing region, and wherein the first or second precursor fluid is a liquid, and having a movement unit configured to move the processing head and/or the sample holder with the optical element relative to one another such that the first outlet, the cleaning arrangement and the second outlet are run successively across the processing region.

This apparatus has the advantage that a greater selection of precursors is available for the at least one liquid precursor than is the case for precursors supplied in gaseous form. Moreover, gaseous precursors frequently have a low vapor pressure, which results in a slow process, or thermal stability problems occur when they are used, which can be avoided with the liquid precursor. It is thus possible in particular to distinctly increase a process speed with the liquid precursor compared to a gaseous precursor, which makes processing more efficient and economically viable. In addition, it is possible to improve selectivity of the process, especially in the case of an atomic layer etching process, by utilizing suitable selective precursors. Moreover, the unutilized fraction of the liquid precursor can be collected and reused, which allows saving of resources. The respective outlet additionally permits spatially restricted, controlled supply and hence processing of particular surface regions of the optical element, which may be advantageous over methods relating to the whole surface.

The expression “atomic layer processing operation” in the present context means atomic layer deposition as mentioned at the outset and atomic layer etching. The atomic layer processing operation may thus be configured either as an atomic layer deposition process or as an atomic layer etching process. In addition, the atomic layer processing operation may first comprise an etching process and then a deposition process. Configuration as a deposition or etching process depends, for example, on the precursors used.

The sample holder holds the optical element in a horizontal position, for example. The sample holder may be suitable for, or designed specially for the purpose of, holding flat optical elements or else curved optical elements. The sample holder holds the optical element in particular so that the optical surface of the optical element, i.e., for example, the reflective surface, faces away from the sample holder. This means that the sample holder holds the optical element from the side in particular and/or supports it from a reverse side.

When the optical element is being held by the sample holder, the processing head is especially arranged opposite the optical surface, such that the processing head can be positioned directly above the optical surface.

In an atomic layer deposition process, first precursor particles of the first precursor fluid are adsorbed on the surface of the optical element in the processing region, forming a monolayer. The monolayer has a layer thickness dependent on the first precursor, which may, for example, be in the range between 0.1 nm-5 nm. Excess first precursor particles, i.e. those that are not adsorbed on the surface, are removed by the cleaning arrangement, for example blown or pumped away. Second precursor particles of the second precursor fluid react with the first precursor particles arranged in the monolayer, and in so doing form a deposit comprising a monolayer of a reaction product. The chemical reaction can also give rise to volatile reaction products. The deposit is in particular bound stably to the surface, such that, for example, a further monolayer may be deposited on the surface, in order to achieve a desired layer thickness by repeated deposition of a monolayer.

In an atomic layer etching process, the first precursor particles of the first precursor fluid react in particular with a surface layer of the optical element in the processing region. A monolayer of an intermediate, for example, is formed. One example of such a process is the formation of a native oxide on an elemental silicon surface in an oxygenous atmosphere. Excess first precursor particles, i.e. those that are not integrated in the monolayer, are removed by the cleaning arrangement, for example blown or pumped away. Second precursor particles of the second precursor fluid react with the first precursor particles and especially with the constituents of the interlayer to form volatile reaction products. The interlayer monolayer is thus removed from the surface. Since the interlayer has been formed with involvement of the atoms or molecules of the surface of the optical element, what takes place is thus effectively material removal (etching). The etching process is self-limiting since the second precursor fluid does not chemically react automatically with the surface of the optical element. The etching process can thus be controlled very exactly and can be ended after attainment of the desired etching depth.

Since the atomic layer processing operation relates in each case only to a monolayer on the surface of the optical element, very good process control is possible. In particular, the surface can be analyzed after each processing run (i.e. deposition or etching), for example by optical and/or electron-optical methods, in order to monitor the progress of the processing operation and to end it when the target of the processing operation has been attained.

The atomic layer processing operation proceeds in a spatially delimited manner. The spatial delimitation is achieved in that the first precursor fluid is supplied by the first outlet only in a limited section of the surface. This means that only the limited surface section is covered by the first precursor fluid. Since this is the prerequisite for occurrence of the corresponding chemical reaction (deposition or etching) as a result of exposure to the second precursor fluid, the processing operation is limited to the surface section. Spatial delimitation of the processing operation can also be achieved by corresponding spatial delimitation of the second precursor fluid.

The spatial region to which the processing operation is limited depends in particular on the configuration of the processing head, especially of the first and second outlets.

One outlet for supply of liquid precursor fluid takes the form of a slot die, for example, as known from slot-die coating. The respective outlet may alternatively be formed in accordance with a different nozzle geometry or else a diffuser geometry.

For performance of the processing operation, the processing head is moved relative to the surface of the optical element such that the first outlet first passes over the processing region, then the cleaning arrangement passes over the processing region and removes excess first precursor fluid from the surface, and then the second outlet passes over the processing region. For example, the first outlet, the cleaning arrangement and the second outlet in the processing head are arranged successively in a first direction, and the processing head is moved over the surface of the optical element in the first direction. The processing region is thus the section of the surface over which the processing head passes. An instantaneous processing region at a particular juncture is the section of the sample surface opposite the processing head.

The cleaning arrangement comprises, in particular, at least one outlet or inlet via which excess first precursor fluid can be removed from the processing region. For example, the first precursor fluid is sucked or pumped out of the processing region via the inlet. In this case, it is only the excess precursor fluid that is removed. This means that those first precursor particles that are part of the monolayer on the surface remain on the surface. The outlet or inlet is arranged spatially between the first outlet and the second outlet, for example, on the processing head.

The cleaning arrangement is preferably formed such that any excess first and/or second precursor fluid and any volatile reaction products from the reaction of the respective precursor fluid with the surface or the monolayer on the surface are removed from the surface.

The cleaning arrangement may especially utilize a capillary effect for suction removal of the liquid precursor (or of further liquid substances on the surface). For example, an opening that forms the outlet and a channel or conduit connected thereto is of such a size that a noticeable capillary force acts on the liquid to be sucked away and hence supports the suction. In this case, the outlet and/or the connected channel may advantageously be coated in order to boost the capillary force.

The first or the second precursor fluid may be atomic (i.e. consist of individual atoms) or else molecular (i.e. consist of molecules comprising multiple atoms), or may comprise both atoms and molecules. The respective precursor fluid may especially also be heterogeneous in that it contains two or more different constituents. A respective precursor fluid may additionally comprise oligomers or else polymers as constituents.

The term “fluid” includes substances that are in liquid form or gaseous form.

In addition, a respective precursor fluid in liquid form may contain a solvent that imparts particular flow properties to the liquid, such that the precursor fluid is applicable with the processing head and collectable by the cleaning arrangement.

What is meant in the present context by the respective precursor fluid being a liquid is that the respective precursor fluid is in the liquid state under the process conditions under which the atomic layer processing operation is conducted and is contacted onto the surface of the optical element by the respective outlet in the liquid state.

The use of a liquid additionally has the advantage that a layer of gas molecules of a surrounding gas atmosphere that has been adsorbed on the surface is displaced by the liquid and/or the gas molecules dissolve in the liquid, such that the surface can be fully wetted by the liquid. This enables rapid and complete formation of the monolayer and/or reaction with the monolayer. The respective liquid can additionally be applied to the surface with an elevated pressure, which can additionally promote the wetting of the surface. What is meant by elevated pressure is, for example, that the pressure of the liquid on the surface is higher than when liquid droplets are at rest on the surface.

In embodiments, the first precursor fluid is a liquid and the second precursor fluid is a gas, or vice versa.

In embodiments, the atomic layer processing operation may comprise more than two steps, where the processing head may have further outlets for supply of further precursor fluids. For example, the processing operation comprises an intermediate step in which the monolayer of the first precursor fluid formed in the first step is first converted to an intermediate, which intermediate has suitable chemical reactivity with the second precursor fluid. Such an intermediate step may also be effected without supply of a further precursor fluid, but rather, for example, by irradiation of the monolayer with electromagnetic radiation of suitable energy and/or with charged particles, such as electrons, protons or ions.

In embodiments of the apparatus, the processing head may comprise a measurement unit for detection of a physical parameter indicative of a state of the surface of the optical element. The state of the surface comprises, for example, information with regard to chemical elements present on the surface, a layer thickness of a layer present on the surface and the like. The measurement unit may be configured, for example, to induce and detect atomic and molecular excitations by through the incidence of light, especially in the infrared region, the energy of which can be used to conclude a chemical composition. Optical reflective methods, for example ellipsometry, can be utilized to ascertain a refractive index and/or a near-surface layer structure.

The processing head may be formed, for example, similarly to a printhead for printing of substrates. The processing head may comprise several elements; in particular, the different outlets encompassed by the processing head may be movable independently. In preferred embodiments, the different outlets are arranged in a fixed manner in the processing head, such that a spatial relation of the outlets to one another is constant.

The movement unit is configured to move the processing head and/or the sample holder with the optical element relative to one another. The movement unit may move both the sample holder and the processing head, or just one of the two. For example, the movement unit comprises a height adjustment unit with which a height of the sample holder or processing head is adjustable, where a distance between the surface of the optical element and an underside of the processing head is adjustable in terms of height, for example. The underside of the processing head is that side in which the outlets of the processing head are disposed.

The movement unit may also comprise a displacement and/or rotation unit configured for lateral displacement of the sample holder and/or of the processing head and/or for rotation of the sample holder and/or the processing head. In addition, the movement unit may be configured to tilt the optical element. By tilting, it is possible to provide an oblique surface in relation to a direction of gravity, which can be utilized in order to steer or influence flow of liquid in the case of a liquid precursor, on which gravity exerts a considerable effect in a gas atmosphere.

In one embodiment of the apparatus, both the first precursor fluid and the second precursor fluid is a liquid.

In a further embodiment of the apparatus, the optical element during the performance of the processing operation is disposed in an inert gas atmosphere having a pressure within a range from 0.01 atm-10 atm, preferably 0.1 atm-5 atm.

A high pressure is advantageous especially when the respective liquid precursor fluid comprises a dissolved gaseous active constituent, since a higher pressure contributes to a higher solubility and hence concentration of the dissolved substance in the liquid. This high ambient pressure is possible because of the use of a liquid precursor, since this is capable of fully wetting the surface in spite of the ambient atmosphere and even without complex surface cleaning steps. Weakly adsorbed gas molecules from the atmosphere are displaced by the liquid. It should be noted that 1 atm=101.325 kPa.

For example, the apparatus has a housing in which the sample holder, the processing head and the movement unit are disposed, which housing is configured to provide the inert gas atmosphere.

In embodiments, the housing may take the form of a vacuum housing and be evacuated, such that there is a vacuum in the housing. By controlled supply of gas to the vacuum housing, it is possible to exactly establish a residual gas composition in the vacuum housing.

In a further embodiment of the apparatus, at least one outlet and/or inlet of the cleaning arrangement is disposed along a path between the first outlet and the second outlet that corresponds to the relative movement between the optical element and the processing head.

For example, the processing head is moved in a linear manner over the surface during the processing. In that case, the outlet and/or inlet of the cleaning arrangement is disposed in particular on a line connecting the first outlet and the second outlet.

In one embodiment, the processing head takes the form of a rotatably mounted head, where an axis of rotation is oriented, for example, at right angles to the surface. Slot-shaped outlets, for example, are integrated in an underside of the head, and extend in radial direction. When the processing head is then rotated, the outlets successively pass over the same surface sections. In this configuration, the outlet and/or inlet of the cleaning arrangement is disposed between the first and second outlets in accordance with the rotary movement.

In a further embodiment of the apparatus, the cleaning arrangement comprises at least one inlet configured for suction removal of the first precursor fluid or the second precursor fluid.

The inlet can also be referred to as suction nozzle.

In embodiments, the cleaning arrangement comprises more than just one outlet or inlet. In particular, the cleaning arrangement may be configured such that an inlet in the form of a suction nozzle fully encloses the first outlet and/or the second outlet, or a separate suction nozzle is provided for each outlet. It is thus possible for any excess precursor fluid to be sucked away through the suction nozzle in any direction proceeding from the outlet of the respective precursor fluid.

In a further embodiment of the apparatus, the at least one inlet opens into a pumped removal channel, and wherein a separation apparatus is disposed along the pumped removal channel and is configured to separate out and collect the pumped-off precursor fluid from the pumped-off fluid.

In the course of suction removal of the liquid, it is especially also possible to suck in gas from an environment of the inlet, such that the fluid sucked in by the inlet may comprise a mixture of the liquid precursor fluid and the ambient gas. The liquid precursor fluid may additionally be atomized by the suction removal and take the form of fine droplets. The separation apparatus preferably separates the liquid constituents from the gaseous constituents. The separation apparatus may comprise, for example, a centrifugal separator and/or may comprise suitable filter media, such as air filters.

The excess liquid precursor fluid may thus be intercepted, collected and reused.

In a further embodiment of the apparatus, the cleaning arrangement comprises a number of inlets for suction removal of fluid and a number of purge fluid outlets for supply of a respective purge fluid.

The purge fluid outlets may be configured to supply gaseous or else liquid purge fluids. Examples of suitable purge fluids are inert gases or liquids. Cleaning of the surface can preferably be achieved by contacting the surface region with solvent or detergent before and/or after the first and/or second precursor fluid has been supplied.

Inert gases are especially suitable for clearing the surface, where the surface may also be dried (blowing-dry). In one embodiment, a supplied gaseous purge fluid is a surfactant, which especially affects a surface tension of a liquid, for example a liquid film of the first or second precursor fluid which is present on the surface. Gradients in surface tension can promote material transfer (from regions of low surface tension toward regions of greater surface tension). This is known, for example, as the Marangoni effect. This effect may especially be utilized for assistance of drying of the surface after application of a liquid precursor or else a liquid purge fluid.

The respective number comprises one or more than one outlet and/or inlet. For example, the cleaning arrangement comprises two or more inlets (suction nozzles) and/or two or more purge fluid outlets. In one embodiment, the suction nozzles and purge fluid outlets are in an alternating arrangement. There is preferably a first suction nozzle adjacent to the first outlet, and a second suction nozzle adjacent to the second outlet. At least one purge fluid outlet is disposed between the two suction nozzles.

In this embodiment, it is ensured in a particularly reliable manner that no remaining free first precursor fluid remains on the surface, which could have the effect that the processing is not limited to the monolayer.

The purge fluid outlet preferably takes the form of an airblade. In this case, a gaseous purge fluid with a high flow velocity is directed onto the surface in a preferably laminar flow. The purge fluid then forms a fluidic curtain having a high flow rate compared to the environment. This curtain “entrains” all free fluidic substances (i.e. those not bound to the surface) in the environment; in particular, free residues of the respective precursor fluid on the surface are thus displaced by the purge fluid.

In a further embodiment of the apparatus, at least one liquid purge fluid is provided.

Liquid purge fluids may have the advantage over gaseous purge fluids that comparatively viscous precursor fluids can also be utilized, since the purge fluid is able to dilute the viscous precursor fluid and hence to improve the flow properties thereof, such that the viscous precursor fluid can nevertheless be removed from the surface without residue.

Especially when the processing operation comprises an atomic layer etching process, a liquid purge fluid additionally has the advantage that nonvolatile reaction products that are only weakly bonded to the surface can be carried away by the purge fluid and hence removed. In this respect, the purge fluid contributes to the erosion of the surface. This opens up new options with regard to the usable precursors since the reaction products need not necessarily be volatile.

In a further embodiment of the apparatus, the processing head comprises a temperature control apparatus to control the temperature of the first and/or second precursor fluid.

The temperature control apparatus may be suitable both for heating and for cooling of the fluid supplied. Depending on whether the respective chemical process that proceeds is an endothermic or exothermic operation, increasing or reducing the temperature of the fluid can increase or reduce the reaction rate. The temperature can therefore be used to influence the kinetics of the atomic layer processing operation, which contributes to better process control.

The temperature control apparatus may be disposed, for example, in a feed for conduction of the respective fluid to the respective outlet.

In embodiments, further temperature control apparatuses in relation to purge fluid supplied may be provided.

In a further embodiment of the apparatus, the first or second precursor fluid is a gas, and the processing head comprises a plasma generator for generation of a plasma from the gaseous precursor fluid.

A plasma generator comprises, for example, an electrical oscillator circuit that generates a magnetic field and/or electrical field that fluctuates with a suitable frequency in the region of the respective outlet or of a feed to the respective outlet. By virtue of the alternating field, charges in the atoms or molecules of the fluid in question are displaced relative to one another. If the energy is high enough, an atom or molecule can be ionized thereby, meaning that an electron is separated from its atom or molecule. There are therefore ions and a quasi-free electron gas in the plasma.

The plasma generator for generating the plasma may be designed in interaction with the sample holder. For example, the sample holder forms a counterelectrode to an electrode disposed in the processing head, such that an electrical field is formed between the processing head and the sample holder.

An illustrative process in which a plasma can be used is the removal of tin deposited on the surface of the optical element. The first precursor fluid is, for example, gaseous oxygen, which is ionized by the plasma generator. In the processing region, the surface is thus exposed to an oxygen plasma that effectively oxidizes the tin. Tin oxide can be effectively dissolved by a strong acid. For example, a second precursor fluid used is therefore liquid hydrochloric acid (HCl).

In a further embodiment of the apparatus, it has a sample temperature control apparatus to control the temperature of the optical element disposed in the sample holder.

The sample temperature control apparatus may be provided alternatively or additionally to the above-described temperature control apparatus of the processing head.

In a further embodiment of the apparatus, the first precursor fluid is an acidic aqueous solution, and the second precursor fluid is an alkaline aqueous solution.

The acidic aqueous solution has, for example, a low pH in the range of 0-6, preferably between 0-4. Such an acidic aqueous solution is capable of oxidizing a surface of a metal. Examples of the acidic aqueous solution are hydrochloric acid, citric acid, acetic acid and the like, where a concentration of the respective acid in the aqueous solution for establishment of a preferred pH of the aqueous solution may be varied. Other acidic solutions may likewise be used.

The alkaline aqueous solution has, for example, a pH between 8-15, preferably between 11-14. Examples of the alkaline aqueous solution are sodium hydroxide solution, aqueous ammonia or the like, where a concentration of the respective substance in the aqueous solution for establishment of a preferred pH of the aqueous solution may be varied. Other basic solutions may likewise be utilized. Such an alkaline solution can be utilized for dissolution of metals, where exposure of the metal to the alkaline solution results in formation of a soluble metal hydroxide, for example.

The respective aqueous solution is preferably buffered, such that the pH of the solution is essentially constant. In particular, weak acids or bases are suitable for provision of the respective buffered solution. A weak acid has, for example, an acid constant (pKa) in the range between 3-13. A weak base has, for example, a base constant (pKb) in the range between 3-13. Weak acids or bases—by contrast with strong acids or bases—are present in the aqueous solution both in protonated and in deprotonated form. An equilibrium between the two forms determines the pH of the solution and buffers changes therein. Acetic acid is an example of a weak acid, the pKa of which is about 4.75. Ammonia dissolved in water is an example of a weak base, the pKb of which is about 4.75.

For example, the optical element to be cleaned has a surface layer of ruthenium. Ruthenium is a comparatively nonreactive precious metal and serves here in particular as protective layer, in order to protect the sensitive silicon-molybdenum multilayer structure that forms a Bragg mirror for EUV radiation from oxidation. During utilization of the optical element in an EUV lithography apparatus, tin (in elemental form or else in the form of various chemical compounds) from the EUV radiation source can be deposited on the surface. These contaminations are to be removed in the processing operation without damaging the ruthenium layer. By exposure of the ruthenium layer to the acidic aqueous solution, it is possible, for example, to form an oxidic passivation layer in the ruthenium (for example RuO₂), and, on exposure of the ruthenium layer to the alkaline aqueous solution, a hydroxidic passivation layer may form (for example Ru(OH)₃). Tin is less stable compared to ruthenium, and therefore it can be dissolved under conditions that do not affect ruthenium (apart from the formation of a passivation layer), for example in alkaline solutions at a pH in the range of 8-12.

In relation to the solubility or reactivity of metals with aqueous acidic or alkaline solutions, it should be pointed out that this can be inferred from what is called a Pourbaix diagram for a respective metal. A Pourbaix diagram is a schematic empirical representation of the electrochemical potential of a metal as a function of the pH of an aqueous solution. In this regard, reference is made to M. Pourbaix: “Atlas of Electrochemical Equilibria in Aqueous Solution”, National Association of Corrosion Engineers, Houston, 1974. DOI:10.1016/0022-0728(67)80059-7. In relation to ruthenium, reference is additionally made to I. Povar, O. Spinu: “Ruthenium redox equilibria 3. Pourbaix diagrams for the systems Ru—H2O and Ru—Cl—H2”, J. Electrochem. Sci. Eng. 6(1) 145(2016 ); DOI:10.5599/jese.229. In relation to tin, reference is additionally made to S. B. Lyon: “Corrosion of Tin and its Alloys” in B. Cottis, M. Graham, R. Lindsay, S. Lyon, T. Richardson, D. Scantlebury, H. Stott, Eds., “Shreir's Corrosion”, Elsevier, 2010, DOI: 10.1016/B978-044452787-5.00099-8.

In embodiments of the apparatus, the liquid purge fluid used between the first precursor fluid and the second precursor fluid is distilled or deionized water. In this way, it is possible to remove all acidic or basic residues and/or other dissolved substances from the surface, which contributes to improved process control. In particular, a chemical reaction which is triggered by contact of the surface with the respective aqueous solution can be stopped by the distilled water through displacement of the aqueous solution. It is thus possible, for example, to restrict continuous processes to an individual atomic layer on the surface by keeping the exposure time very short through rapid movement of the processing head. Preferably, the surface is rinsed with distilled water both after the first precursor fluid and after the second precursor fluid.

In further embodiments, the first precursor fluid is an alkaline aqueous solution and the second precursor fluid is an acidic aqueous solution.

In a further embodiment of the apparatus, the first and/or second precursor fluid additionally comprises an oxidizing agent.

Examples of oxidizing agents dissolved in the aqueous solution are as follows: nitrate ions (NO₃⁻), nitrite ions (NO₂⁻), persulfate ions (S₂O₈²⁻), thiosulfate ions (S₂O₃ ²⁻), hydroperoxide ions (HO²⁻), chlorite ions (ClO²⁻), hypochlorite ions (ClO⁻), iodate ions (IO₃⁻) and/or nitroaromatic ions, such as 3-nitrobenzenesulfonate (C₆H₄(NO₂)SO₃) or 3-nitrobenzoate (C₆H₄(NO₂)CO₂⁻).

For dissolution of tin in alkaline aqueous solutions, iodate ions and nitroaromatic ions have been found to be particularly effective, and therefore these are used with preference. In this regard, reference is made to the article Y. K. Taninouchi and T. Uda: “Rapid Oxidative Dissolution of Metallic Tin in Alkaline Solution Containing Iodate Ions”, J. of Sustainable Metallurgy, 7, 1762 (2021); DOI: 10.1007/s40831-021-00450-3.

In a further embodiment of the apparatus, the apparatus also has a measurement apparatus for detecting a distance between the processing head and the surface of the optical element, wherein the movement unit is configured to move the processing head and/or the optical element at a predetermined distance from one another.

This ensures that the processing operation is spatially limited in that the respective precursors are conducted into the respective processing region in a controlled manner. A relatively small distance is advantageous here, but the open-loop and closed-loop control complexity for establishment and maintenance of the distance is also greater when the distance is smaller.

The processing head is guided over a particular surface during processing thereof, especially at a predetermined distance. The distance is, for example, in the range between 1 μm-100 mm, preferably between 10 μm-10 mm, more preferably between 50 μm-1 mm, further preferably between 50 μm-500 μm. The predetermined distance relates in particular to a smallest distance between the processing head and the surface. The distance is advantageously chosen such that the fluid supplied forms an essentially laminar flow. The processing head may be structured on its underside, for example in order to steer or to influence a fluid flow, where a distance may vary in the structured regions. In addition, for example in the region of the first and/or second outlet, the distance may be greater, especially when a liquid precursor is being supplied via the outlet in question.

The measurement device is preferably disposed on the processing head, for example in the manner of a laser distance meter or an optical interferometer. There are preferably measurement devices provided at multiple positions on the processing head, such that tilting of the processing head with respect to the surface of the optical element can be detected.

In a further embodiment of the apparatus, the optical element has a surface which is curved in sections, and an underside of the processing head which is opposite the optical element during the processing operation has a shape matched to the curvature.

For example, the optical element is a collector having a particular radius of curvature. Because the processing head is matched to the radius of curvature, it is possible to achieve a uniform distance between the processing head and the surface, such that the processing operation can also be performed efficiently on the curved surface.

In a second aspect, a method of processing a surface of an optical element of a lithography apparatus, especially an EUV lithography apparatus, in an atomic layer processing operation is proposed. The method comprises the following steps:
arranging the optical element on a sample holder,
positioning a processing head opposite the surface of the optical element, such that a first supply outlet of the processing head is disposed opposite a processing region on the surface,
moving the processing head and/or the optical element such that the first supply outlet is moved across the processing region, wherein, during the movement, with the first supply outlet, a first precursor fluid is supplied to the processing region,
moving the processing head and/or the optical element, such that a cleaning arrangement of the processing head is moved across the processing region, wherein the cleaning arrangement is set up to remove excess first precursor fluid from the processing region, and
moving the processing head and/or the optical element such that a second supply outlet of the processing head is moved across the processing region, wherein, during the movement, with the second supply outlet, a second precursor fluid is supplied to the processing region,
wherein the first and second precursor fluids are selected in order to perform an atomic layer deposition process or an atomic layer etching process in the processing region, and wherein the first and/or second precursor fluid is a liquid.

The embodiments and features described for the apparatus in accordance with the first aspect are correspondingly applicable to the proposed method, and vice versa.

In a third aspect, a method of repairing a lithography apparatus, especially an EUV lithography apparatus, is proposed. In a first step, an optical element is removed from a beam path of the lithography apparatus, wherein the optical element has contamination and/or damage on a surface of incidence. In a second step, the optical element is processed in a processing method according to the second aspect. In a third step, the processed optical element is installed into the lithography apparatus again.

The optical element, the surface of which is being processed in the present context, is especially part of an optical system, such as a projection optical unit or an illumination system of a lithography apparatus. The lithography apparatus may be an EUV lithography apparatus. EUV stands for “extreme ultraviolet” and denotes a wavelength of the operating light of between 0.1 nm and 30 nm. The projection exposure apparatus may also be a DUV lithography apparatus. DUV stands for “deep ultraviolet” and refers to a wavelength of the working light of between 30 nm and 250 nm.

“A” or “an” or “one” in the present case should not necessarily be understood to be restrictive to exactly one element. Instead, a plurality of elements, such as for example two, three or more, may also be provided. Nor should any other numeral used here be understood to the effect that there is a restriction to exactly the stated number of elements. Instead, unless indicated otherwise, numerical variances upward and downward are possible.

Further possible implementations of the invention also include combinations which have not been mentioned explicitly of features or embodiments described above or hereinafter with regard to the working examples. In this case, a person skilled in the art will also add individual aspects as improvements or supplementations to the respective basic form of the invention.

Further advantageous configurations and aspects of the invention are the subject of the dependent claims and of the working examples of the invention that will be described hereinafter. The invention is elucidated in detail hereinafter on the basis of preferred embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of a first working example of an apparatus for processing a surface of an optical element of a lithography apparatus;

FIGS. 3A-3C show a schematic of the performance of a spatial atomic layer processing operation in a processing region of a surface of an optical element, in which solely a first precursor is supplied (FIG. 3A), then both the first precursor and a second precursor are supplied (FIG. 3B), and thereafter solely the second precursor is supplied (FIG. 3C) to the processing region;

FIG. 4 shows a schematic of a first working example of a processing head;

FIG. 5 shows a schematic of a second working example of a processing head;

FIG. 6 shows a schematic of a third working example of a processing head;

FIG. 7 shows a schematic view of a second working example of an apparatus for processing a surface of an optical element of a lithography apparatus;

FIG. 8 shows a schematic view of a third working example of an apparatus for processing a curved surface of an optical element of a lithography apparatus;

FIGS. 9A and 9B show two schematic views (side and top view, respectively) of a fourth working example of an apparatus for processing a surface of an optical element of a lithography apparatus; and

FIG. 10 shows a schematic block diagram of a working example of a method of processing a surface of an optical element of a lithography apparatus.

### DETAILED DESCRIPTION

Unless indicated to the contrary, elements that are the same or functionally the same have been given the same reference signs in the figures. It should also be noted that the illustrations in the figures are not necessarily true to scale.

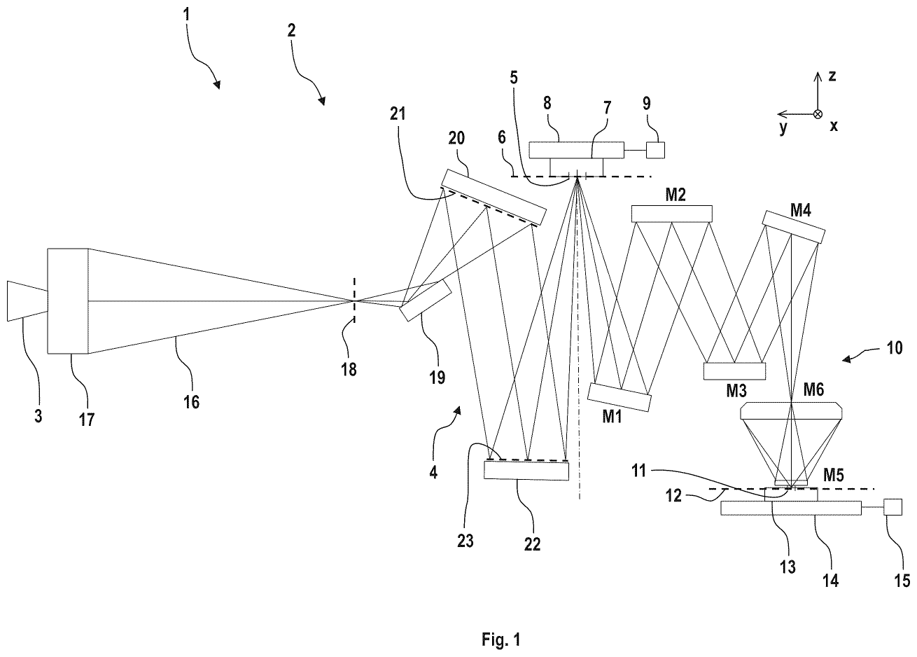

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not include the light source 3.

A reticle 7 arranged in the object field 5 is exposed. The reticle 7 is held by a reticle holder 8. The reticle holder 8 is displaceable by a reticle displacement drive 9, in particular in a scanning direction.

FIG. 1 shows, by way of illustration, a Cartesian coordinate system with an x direction x, a y direction y, and a z direction z. x direction x runs perpendicularly into the plane of the drawing. y direction y runs horizontally, and z direction z runs vertically. The scanning direction in FIG. 1 runs in y direction y. z direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle other than 0°between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by a wafer displacement drive 15, in particular in y direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. Alternatively or additionally, the deflection mirror 19 may be implemented as a spectral filter, which separates a useful light wavelength of the illumination radiation 16 from extraneous light having a different wavelength. If the first facet mirror 20 is arranged in a plane of the illumination optical unit 4 which is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may take the form of macroscopic facets, in particular as rectangular facets or as facets with an arcuate or part-circular edge contour. The first facets 21 may take the form of plane facets or alternatively as convex curved or concave curved facets.

As is known, for example, from DE 10 2008 009 600 A1, the first facets 21 themselves may each also be composed of a multiplicity of individual mirrors, in particular a multitude of micromirrors. The first facet mirror 20 may be configured in particular as a microelectromechanical system (MEMS system). For details, reference is made to DE 10 2008 009 600 A1.

The illumination radiation 16 propagates horizontally, i.e. in y direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 may also be spaced apart from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may also be macroscopic facets, which may be circularly, rectangularly or else hexagonally delimited, for example, or alternatively may be facets composed of micromirrors. In this regard, reference is again made to DE 10 2008 009 600 A1.

The second facets 23 may have flat or alternatively convex or concave curved reflection surfaces.

The illumination optical unit 4 thus forms a double-faceted system. This fundamental principle is also referred to as a fly's eye integrator.

It may be advantageous to arrange the second facet mirror 22 not exactly within a plane that is optically conjugate to a pupil plane of the projection optical unit 10. In particular, the second facet mirror 22 may be arranged so as to be tilted in relation to a pupil plane of the projection optical unit 10, as described for example in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or else, alternatively, two or more mirrors, which are arranged in succession in the beam path of the illumination optical unit 4. The transfer optical unit might in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so the illumination optical unit 4 may then have exactly two mirrors downstream of the collector 17, specifically the first facet mirror 20 and the second facet mirror 22.

The imaging of the first facets 21 into the object plane 6 by the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi may take the form of freeform surfaces without an axis of rotational symmetry. Alternatively, the reflection surfaces of the mirrors Mi may take the form of aspherical surfaces with exactly one axis of rotational symmetry of the reflection surface shape. Just like the mirrors of the illumination optical unit 4, the mirrors Mi may have highly reflective coatings for the illumination radiation 16. These coatings may take the form of multilayer coatings, in particular with alternating layers of molybdenum and silicon.

The projection optical unit 10 has a large object-image offset in y direction y between a y coordinate of a center of the object field 5 and a y coordinate of the center of the image field 11. This object-image offset in y direction y may be of approximately the same magnitude as a z distance between the object plane 6 and the image plane 12.

In particular, the projection optical unit 10 may have an anamorphic design. It has in particular different imaging scales βx, βy in x and y directions x, y. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in x direction x, i.e. in a direction perpendicular to the scanning direction.

The projection optical unit 10 leads to a reduction in size of 8:1 in y direction y, i.e. in scanning direction.

Other imaging scales are likewise possible. Imaging scales with the same sign and the same absolute value in x direction x and y direction y are also possible, for example with absolute values of 0.125 or of 0.25.

The number of intermediate image planes in x direction x and in y direction y in the beam path between the object field 5 and the image field 11 may be the same or may differ, depending on the embodiment of the projection optical unit 10. Examples of projection optical units with different numbers of such intermediate images in x direction x and y direction y are known from US 2018/0074303 A1.

In each case, one of the second facets 23 is assigned to exactly one of the first facets 21 for forming in each case an illumination channel for illuminating the object field 5. This may in particular result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid over one another for the purpose of illuminating the object field 5. The illumination of the object field 5 is in particular as homogeneous as possible. It preferably has a uniformity error of less than 2%. Field uniformity can be achieved by overlaying different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner may be achieved by a redistribution of the illumination channels.

Further aspects and details of the illumination of the object field 5 and in particular of the entrance pupil of the projection optical unit 10 are described hereinafter.

The projection optical unit 10 may have a homocentric entrance pupil in particular. It may be accessible. It may also be inaccessible.

The entrance pupil of the projection optical unit 10 regularly cannot be exactly illuminated with the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. In particular, this area exhibits a finite curvature.

It may be the case that the projection optical unit 10 has different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different positions of the tangential entrance pupil and the sagittal entrance pupil may be taken into account.

In the arrangement of the component parts of the illumination optical unit 4 illustrated in FIG. 1, the second facet mirror 22 is arranged in an area conjugate to the entrance pupil of the projection optical unit 10. The first facet mirror 20 is in a tilted arrangement in relation to the object plane 6. The first facet mirror 20 is in a tilted arrangement in relation to an arrangement plane defined by the deflection mirror 19. The first facet mirror 20 is in a tilted arrangement in relation to an arrangement plane defined by the second facet mirror 22.

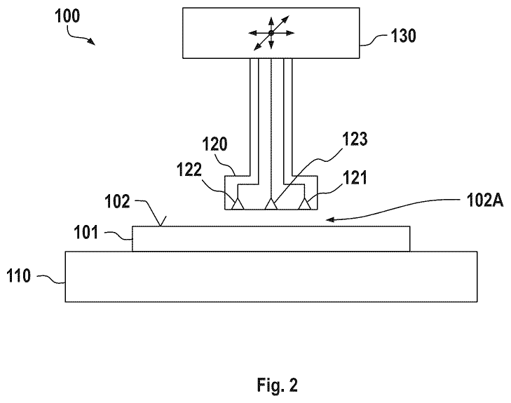

FIG. 2 shows a schematic view of a first working example of an apparatus 100 for processing a surface 102 of an optical element 101 of a lithography apparatus 1, for example the projection exposure apparatus shown in FIG. 1. The optical element 101 is, for example, one of the optical elements of the illumination system 2, of the illumination optical unit 4 or of the projection optical unit 10 as shown in FIG. 1. In particular, the optical element can be the collector 17, one of the deflection mirrors 19 and/or facets 21, 23 of the first facet mirror 20 or of the second facet mirror 22.

The apparatus 100 comprises a sample holder 110 to hold the optical element 101 during the processing operation, a processing head 120 disposed opposite and above the surface 102 to be processed of the optical element 101, and a movement unit 130. The processing head 120 in this example comprises a first supply outlet (outlet) 121, a second supply outlet (outlet) 122, and a cleaning arrangement 123.

In this example, the processing head 120 is disposed on the movement unit 130, where the movement unit 130 is configured to move the processing head 120 relative to the surface 102 of the optical element 101. The movement unit 130 may have one or more degrees of freedom, for example up to three linear degrees of freedom (displacement in three spatial directions x, y, z) and up to three rotational degrees of freedom (rotation about three axes).

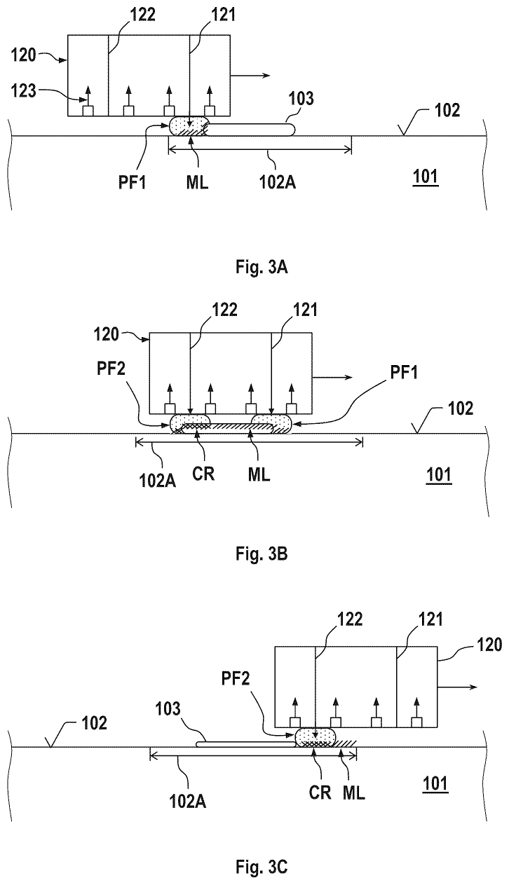

The first outlet 121 is arranged to supply a first precursor fluid PF1 (see FIGS. 3A-3C, 4, 5, 7) to a processing region 102A on the surface 102 of the optical element 101. The cleaning arrangement 123 comprises, in particular, an outlet or inlet for removal of excess first precursor fluid PF1 from the processing region 102A. The second outlet 122 is arranged to supply a second precursor fluid PF2 (see FIGS. 3A-3C, 4, 5, 7) to the processing region 102A. The first precursor fluid PF1 and the second precursor fluid PF2 are selected such that an atomic layer deposition process or an atomic layer etching process takes place in the processing region 102A when the surface 102 is exposed first to the first precursor fluid PF1 and then to the second precursor fluid PF2. In the present context, this is achieved in that the movement unit 130 moves the processing head 120 along a corresponding pathway across the surface 102 and the processing region 102A. In order to restrict the process to a monolayer ML (see FIGS. 3A-3C), excess first precursor fluid PF1 after the applying of the first precursor fluid PF1 is removed from the processing region 102A by the cleaning arrangement 123 before the second precursor fluid PF2 is supplied. The spatial separation between the first and second outlets 121, 122 in the processing head 120 and the intervening cleaning arrangement 123 ensures that the precursor fluids PF1, PF2 do not mix with one another. The first precursor fluid PF1 and/or the second precursor fluid PF2 is a liquid.

The atomic layer deposition process or atomic layer etching process is elucidated in detail hereinafter with reference to FIGS. 3A-3C. FIGS. 3A-3C show a schematic of the performance of a spatial atomic layer processing operation in a processing region 102A of a surface 102 of an optical element 101. The process described hereinafter can be performed, for example, with the apparatus 100 from FIGS. 2, 7, 8, 9A, 9B.

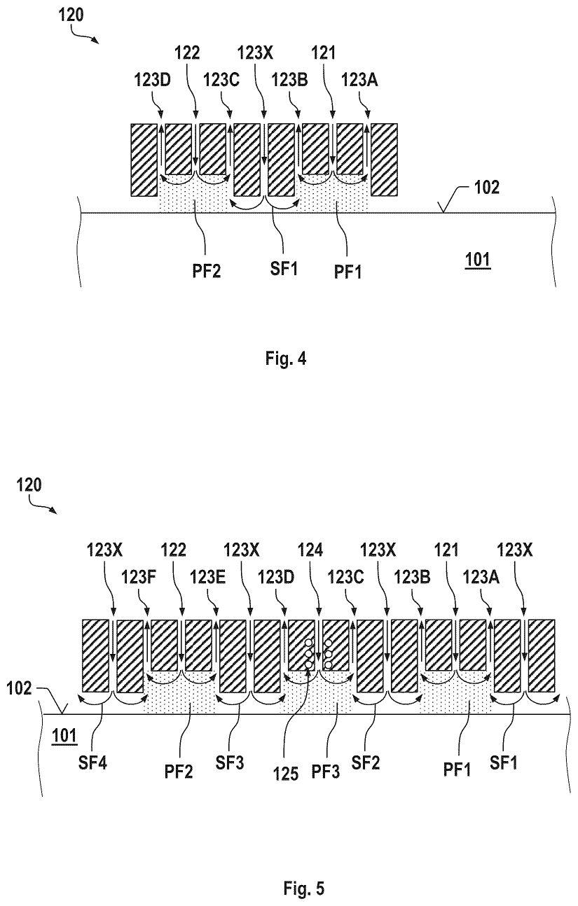

For reasons of clarity, FIGS. 3A-3C show only a detail of the optical element 101 and the processing head 120. More detailed illustrations of the processing head 120 are shown in FIGS. 4 and 5.

A contamination 103 is present on the surface 102 in a processing region 102A. This is, for example, a tin deposit. The tin 103 comes, for example, from the EUV light source of the lithography apparatus in which the optical element 101 has been used.

In FIG. 3A, the processing head 120 is shown at a first position above the processing region 102A. In this position, solely the first outlet 121 is above the processing region 102A. On both sides alongside the first outlet 121, inlets (suction nozzles) of the cleaning arrangement 123 are shown schematically (for example, the suction nozzle surrounds the first outlet 121 completely). For example, a first liquid precursor PF1 is supplied via the first outlet 121. This propagates in the region bounded by the suction nozzle between the processing head 120 and the surface 102. The first precursor PF1 forms a monolayer ML at the contact surface between the first precursor PF1 and the surface 102. In the region of the surface 102 not wetted by the contamination 103, for example, first precursor particles are adsorbed on the surface 102. Where the first precursor PF1 comes into contact with the contamination 103, a chemical reaction in particular takes place between near-surface atoms of the contamination 103 and first precursor particles. A monolayer ML of an intermediate is formed here. For example, the tin is oxidized, resulting in a tin oxide monolayer. The monolayer ML has a layer thickness, for example, of 0.1 nm- 2 nm.

The processing head 120 is moved across the processing region 102A, which is indicated schematically by the arrow. It should be noted that it is also possible for the optical element 101 to pass beneath the processing head 120. A width of the processing region 102A into the image plane is fixed by the width of the processing head 120, especially the first and second outlets 121, 122. In FIG. 3A, the second outlet 122 is not yet disposed above the processing region 102A, and therefore no second precursor fluid PF2 is being supplied.

FIG. 3B shows how the processing head 120 is moved further across the processing region 102A, leaving the monolayer ML on the surface 102 in the regions that have come into contact with the first precursor PF1. Excess first precursor fluid PF1 is sucked away. In FIG. 3B, the second outlet 122 is likewise disposed above the processing region 102A, and therefore second precursor fluid PF2 is also being supplied. The second outlet 122 in this example is likewise surrounded by a suction nozzle of the cleaning arrangement 123, such that the second precursor fluid PF2 is restricted to the spatial region bounded by the suction nozzle, the processing head 120 and the surface 102. The second precursor fluid PF2 is, for example, a strong acid, such as hydrochloric acid HCl, which is likewise supplied in liquid form.

Second precursor particles of the second precursor PF2 come into contact with the monolayer ML of the first precursor or intermediate at the surface 102. A chemical reaction CR takes place between the atoms of the monolayer ML and the particles of the second precursor PF2, forming volatile compounds in particular. This leads in particular to erosion of the intermediate monolayer ML of tin oxide. The tin oxide monolayer ML is thus removed or etched by the chemical reaction CR. This leads to effective etching of the contamination 103. In this example, the contamination 103 has a thickness of several monolayers, and therefore tin 103 still remains on the surface 102 after the first atomic layer etching process described, as shown in FIG. 3C. Repeated processing, i.e. multiple performance of the steps described, allows the contamination 103 to be removed without residue.

Since the chemical reaction CR proceeds solely in the region of the intermediate monolayer ML, this atomic layer etching process is selective and limited to the contamination 103. Damage to the surrounding surface 102 therefore advantageously does not take place.

It should be noted that, rather than the etching process illustrated by way of example, a deposition process is performable in the same way when different precursors PF1, PF2 are used. An atomic monolayer deposited in such a deposition process forms wherever the monolayer ML of the first precursor PF1 is present on the surface 102.

FIG. 4 shows a schematic of a cross section of a first working example of a processing head 120 which can be used, for example, in the apparatus 100 from FIG. 2, 7, 8 or 9A, 9B and is suitable for performance of the atomic layer processing operation elucidated by FIGS. 3A-3C.

The processing head 120 in FIG. 4 has two outlets 121, 122 for supply of a first precursor fluid PF1 or a second precursor fluid PF2. The first and second outlets 121, 122 are, for example, each surrounded by an inlet 123A-123D of the cleaning arrangement 123 that takes the form of a suction nozzle (see FIG. 2 or 3A-3C), such that the respective precursor fluid PF1, PF2 is unable to escape from the bounded region between the respective suction nozzles 123A-123D.

In addition, the cleaning arrangement 123 in this example comprises a purge fluid outlet 123X arranged to supply a purge fluid SF1. The purge fluid SF1 may be liquid or else gaseous. For example, the purge fluid SF1 is an inert gas, such as nitrogen, which is supplied at a high flow rate, such that the surface 102 is dried. It is thus possible with the purge fluid outlet 123X to ensure that no free first precursor fluid remains on the surface.

This example likewise shows that the processing head 120 may have a certain degree of structuring on its underside. For instance, the underside of the processing head 120 is set back a little in the region of the first and second outlets 121, 122, such that a chamber is formed between the processing head 120 and the surface 102, in which the respective precursor fluid PF1, PF2 circulates. At the side of the first and second outlets 121, 122, the processing head 120 contains further elements that project closer to the surface 102. For instance, a gap that bounds the chamber is formed between these elements and the surface 102, which has a width of only a few micrometers for example, which impairs fluid flow to the outside. If the suction nozzles are additionally subjected to a sufficient reduced pressure, the respective chamber can be brought to a reduced pressure relative to a surrounding atmosphere, such that the respective precursor fluid PF1, PF2 is still stopped from exiting through the gap.

FIG. 5 shows a schematic of a cross section of a second working example of a processing head 120 which can be used, for example, in the apparatus 100 from FIG. 2, 7, 8 or 9A, 9B and is suitable for performance of the atomic layer processing operation elucidated by FIGS. 3A-3C .

The processing head 120 in this example has three outlets 121, 122, 124 for supply of a respective precursor fluid PF1, PF2, PF3. The additional outlet 124 additionally has a plasma generator 125 which is configured to ionize a precursor gas PF3 fed in via the outlet 124, such that it takes the form of a plasma. A plasma may especially be suitable for activation of particular chemical reactions having a high activation energy. It should be noted that the first and/or second outlet 121, 122 may also have a plasma generator 125, and that the first precursor fluid PF1 or the second precursor fluid PF2 supplied may be a gas which is excited to a plasma state by the plasma generator 125.

The processing head 120 additionally has a multitude of suction nozzles 123A-123F. Additionally shown are four purge fluid outlets 123X, each set up to supply a respective purge fluid SF1-SF4. For example, the purge fluid SF1 supplied is a solvent, in order to clean the surface 102 prior to contact with the first precursor PF1. The purge fluids SF2, SF3 and SF4 are intended, for example, as fluidic curtains in particular for separation of the regions in which the precursors PF1, PF2, PF3 are present. For example, these are inert gases or liquids. For example, the two purge fluid outputs 123X for the purge fluids SF2, SF3 each form an airknife.

It should be noted that the processing head 120 may also have more than the inlets and/or outlets shown here, and/or the outlets and inlets are integrated in the processing head 120 in a different arrangement.

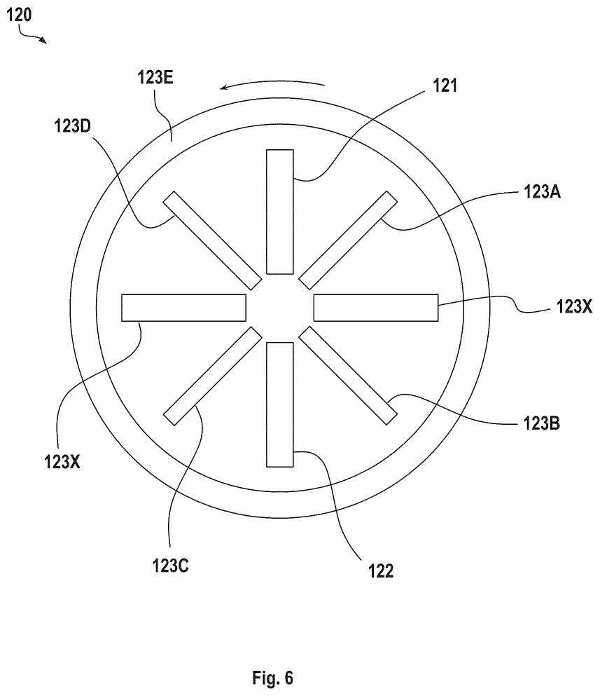

FIG. 6 shows a schematic view of an underside of a third working example of a processing head 120 which can be used, for example, in the apparatus 100 from FIG. 2, 7, 8 or 9A, 9B and is suitable for performance of the atomic layer processing operation elucidated by FIGS. 3A-3C .

In FIG. 6, the processing head 120 is round. Several inlets and outlets 121, 122, 123A-123E, 123X are integrated in the underside. These are a first outlet 121 for supply of a first precursor fluid PF1, a second outlet 122 for supply of a second precursor fluid PF2, two purge fluid outlets 123X for supply of a respective purge fluid SF1 - SF4, and several suction nozzles 123A-123E for suction removal of excess precursor fluid PF1, PF2 or purge fluid SF1 - SF4. When the processing head 120 is rotated, as indicated by the arrow, the inlets and outlets 121, 122, 123A-123D, 123X successively cover the same surface sections of an optical element 101 disposed opposite the processing head. It is thus possible with this processing head 120 to conduct a spatial atomic layer processing operation as described above. An annular suction nozzle 123E ensures, for example, that the precursor fluids PF1, PF2 or purge fluids SF1-SF4 supplied do not leave the region between the processing head 120 and the surface 102 of the optical element 101.

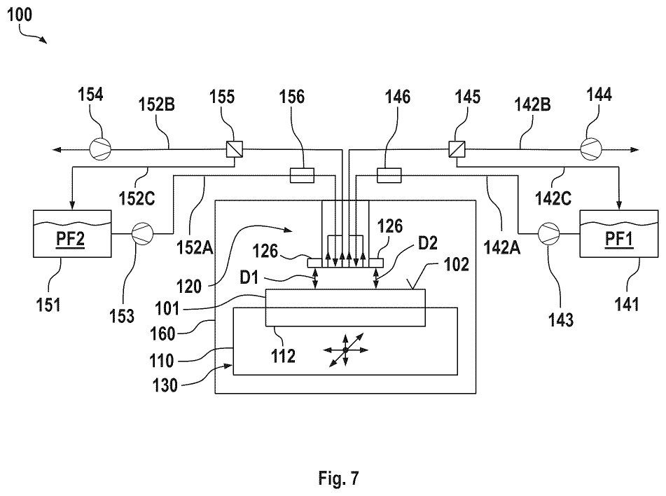

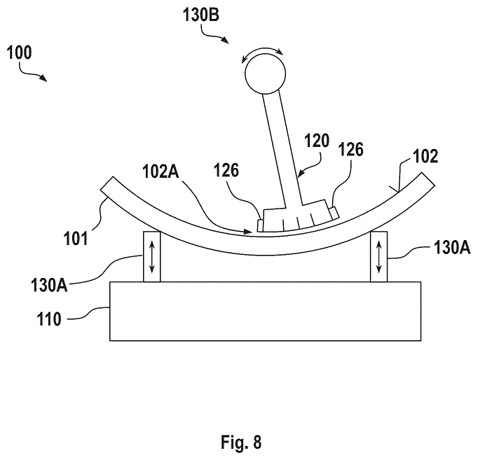

FIG. 7 shows a schematic view of a second working example of an apparatus 100 for processing a surface 102 of an optical element 101 of a lithography apparatus 1. The apparatus 100 has all elements of the apparatus 100 of FIG. 1, which will therefore not be described again here. The movement unit 130 in this example is part of the sample holder 110, for example an x-y-z stage. The movement unit 130 may additionally be configured for rotation of the sample holder 110 about one or more axes, and hence especially also for tilting of the sample holder 110 and hence the optical element 101 (see also FIG. 8 in this regard). The sample holder 110 additionally has a temperature control 112 which is configured to heat or cool the optical element 101. Controlling the temperature of the optical element 101 allows the atomic layer processing operation to be influenced.

In addition, the apparatus in this example comprises a housing 160 in which the sample holder 110, the processing head 120 and the movement unit 130 are disposed. The housing 160 may take the form of a vacuum housing, or else it serves to provide an inert gas atmosphere for the processing operation. The housing 160 is optional.

The processing head 120, shown here in simplified and schematic form, may be designed as detailed in FIGS. 4-6. In addition, two measurement devices 126 are disposed on the processing head 120. These are configured to detect a respective distance D1, D2 from the surface 102 of the optical element 101. The respectively detected distance D1, D2 can advantageously be used for open-loop or closed-loop control of the movement unit 130, for example in order to establish a predetermined distance and to keep it constant during a relative movement between processing head 120 and optical element 101. The measurement devices 126 may alternatively or additionally be configured to analyze the surface 102, for example in order to detect a chemical composition, a layer structure or the like. The measurement devices 126 may then be used for direct process control after each atomic layer processing operation. For example, the measurement devices 126 comprise spectral ellipsometers and/or infrared spectrometers.

It is also possible to provide one or more measurement devices (not shown) on or against the sample holder 110 and laterally to the optical element 101, which may be configured to measure the distance between the processing head 120 and the surface 102. This is advantageous in the case of planar surfaces 102 in particular.

The first precursor fluid PF1 is held in a reservoir 141. This is a liquid by way of example. The precursor fluid PF1 can be fed to the processing head 120 and the first outlet 121 via a conduit 142A in which there is disposed a pump 143 (see FIGS. 2-6). Additionally disposed in the feed conduit 142A is a temperature control 146 configured to heat or to cool the first precursor fluid PF1 before it is fed into the processing region 102A (see FIGS. 3A-3C).

Excess precursor fluid PF1 is sucked out via suction nozzles 123A-123F (see FIGS. 3A-6). The reduced pressure needed for the purpose is provided, for example, by a pump 144 in a conduit 142B. A separation device 145 is disposed in the suction conduit, which can also be referred to as pumped removal channel. The separation device 145 separates liquid constituents of the fluid that has been removed by suction from gaseous constituents. Thus, the excess precursor fluid PF1 that has been removed by suction is removed and can be returned to the reservoir 141 via a conduit 142C.

These details apply correspondingly to the second precursor fluid PF2, which is conveyed and processed via corresponding conduits 152A-152C, pumps 153, 154, temperature control 156 and separators 155.

FIG. 8 shows a schematic view of a third working example of an apparatus 100 for processing a surface 102 of an optical element 101 of a lithography apparatus 1 (see FIG. 1). The apparatus 100 has all elements of the apparatus 100 of FIG. 1, which will therefore not be described again here.

In this example, the optical element 101 has a curved surface 102; for example, this is the collector 17 of the illumination system 2. It should be noted that the curvature of the surface 102 in this example is exaggerated in order to make it clearly visible. In order to obtain a uniform distance between the underside of the processing head 120 and the surface 102, the processing head is matched to the curvature of the surface 102 on its underside (the face of the processing head 120 opposite the surface 102). This means that the underside of the processing head 120 has, for example, the same radius of curvature as the surface 102, where the surface 102 is concave and the underside of the processing head 120 is convex. In embodiments, this may also be reversed.

The processing head 120 in this example is shown merely schematically. The processing head 120 may be designed as depicted by FIGS. 4-6, with regard to the curved underside. The processing head 120 in this example also has two measurement devices 126, for which the elucidations with regard to FIG. 7 are correspondingly applicable. The measurement devices 126 are especially configured to measure the distance between the processing head 120 and the surface 102, since, in the case of a curved surface 102, without such constant monitoring of the distance, collision of the processing head 120 with the surface 102 may rapidly arise in the case of movement of the processing head 120 relative to the surface 102.

In this example, the movement unit 130 comprises two separate units 130A, 130B. Unit 130A is configured, for example, exclusively for a height adjustment of the optical element. When unit 130A is duplicated, as shown here, it is additionally possible to undertake tilting of the optical element 101. This means that the movement unit 130A comprises or forms a tilt unit. For this purpose, three units 130A are preferably provided, which can support and correspondingly move the optical element 101 (or a receptacle for the optical element 101). The units 130A are especially actuated by the measurement devices 126 in an open-loop and/or closed-loop control circuit, in order to establish a particular distance between the surface 102 and the processing head 120 and to avoid collision. Unit 130B in this example is designed as a pivot unit for pivoting of the processing head 120. This means that the processing head 120 can be positioned at different positions across the surface 102, such that the processing region 102A is selectively addressable.

With the tilt unit, it is also possible to arrange the surface 102 of the optical element 101 beneath the processing head 120 at a particular slope in relation to a direction of gravity. A liquid precursor will flow on an oblique surface, especially in the direction of the gravity gradient, which can be utilized in order to impose a flow direction on the precursor supplied (or else on a liquid purge fluid).

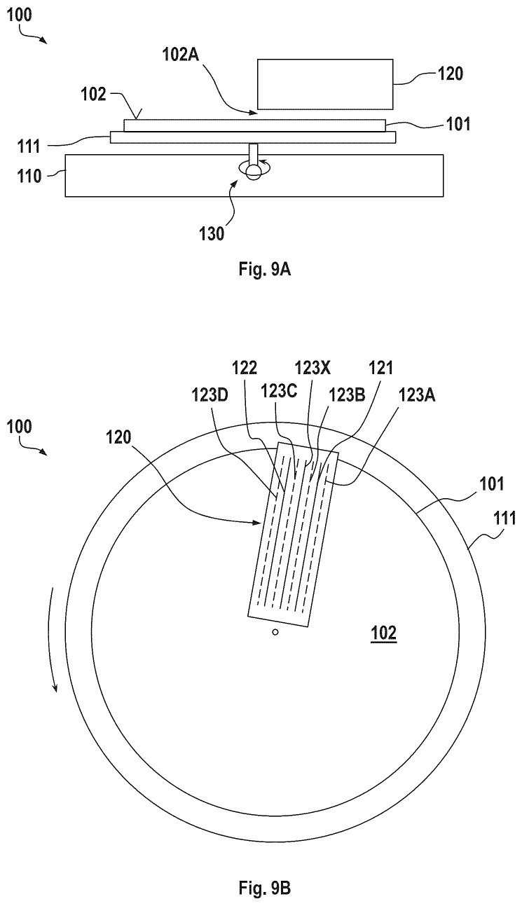

FIGS. 9A and 9B show two schematic views of a fourth working example of an apparatus 100 for processing a surface 102 of an optical element 101 of a lithography apparatus 1 (see FIG. 1), where FIG. 9A shows a schematic side view and FIG. 9B a schematic top view of the apparatus 100.

In this example, the sample holder 110 has a rotatably mounted table 111, and the movement unit 130 is configured as a motor to drive (rotate) the table 111. The processing head 120 is disposed above the table 111, such that an optical element 101 held on the table 111 runs beneath the processing head 120 when the table 111 is rotated. The processing head 120 has a rectangular, elongated shape and is arranged above the table 111 such that the long side extends in essentially radial direction from a center (pivot point) of the table 111 outward.

FIG. 9B shows the processing head 120 in detail. This comprises a first outlet 121, a second outlet 122, several suction nozzles 123A-123D and a purge fluid outlet 123X. The suction nozzles 123A-123D and the purge fluid outlet 123X collectively form a cleaning arrangement 123. The processing head 120 in this example is especially disposed at a fixed location, where the spatial atomic layer processing operation is achieved by movement of the optical element 101 beneath the processing head 120 by the rotary table 111.

It should be noted that, with this configuration, it is also possible to process optical elements 101 that are not circular and/or do not cover the whole table 111. These are then disposed on the table 111, for example, such that the axis of rotation of the table 111 is not covered.

In one embodiment (not shown separately), rather than the rotary table, for example, a conveyor belt is provided, which runs the optical element 101 beneath the processing head 120.

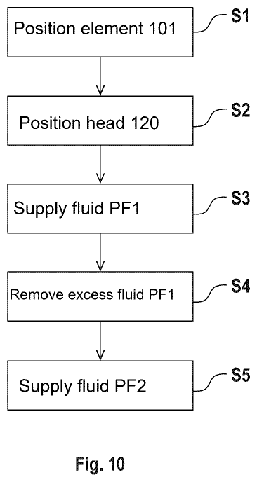

FIG. 10 shows a schematic block diagram of a working example of a method of processing a surface 102 (see FIGS. 2-5, 7-9) of an optical element 101 (see FIGS. 2-5, 7-9) of a lithography apparatus 1 (see FIG. 1) in an atomic layer processing operation as explained with reference to FIGS. 3A-3C for example. In a first step S1, the optical element 101 is positioned in a sample holder 110 (see FIGS. 2, 7-9B) . In a second step S2, a processing head 120 (see FIGS. 2-9B) is positioned opposite the surface 102 of the optical element 101, such that a first outlet 121 of the processing head 120 is disposed opposite a processing region 102A (see FIGS. 2, 3A-3C, 8, 9A, and 9B) on the surface 102. In particular, the processing head 120 is brought here to a predetermined distance from the surface 102, for example a distance between 1 μm-100 mm, preferably between 10 μm-10 mm, more preferably between 50 μm-1 mm, further preferably between 50 μm-500μm. In a third step S3, the processing head 120 and/or the optical element 101 is moved such that the first outlet 121 is moved across the processing region 102A, wherein, during the movement, via the first outlet 121 (see FIGS. 2-6, 9B), a first precursor fluid PF1 (see FIGS. 3-5, 7) is supplied to the processing region 102A. In a fourth step S4, the processing head 120 and/or the optical element 101 is moved onward such that a cleaning arrangement 123 (see FIGS. 2-6, 9B) of the processing head 120 is moved across the processing region 102A, wherein the cleaning arrangement 123 is configured to remove excess first precursor fluid PF1 from the processing region 102A. In a fifth step S5, the processing head 120 and/or the optical element 101 is moved onward such that a second outlet 122 (see FIGS. 2-6, 9B) of the processing head 120 is moved across the processing region 102A, wherein, during the movement, via the second outlet 122, a second precursor fluid PF2 (see FIGS. 3A-5, 7) is supplied to the processing region 102A. The first and second precursor fluids PF1, PF2 are selected in order to perform an atomic layer deposition process or an atomic layer etching process in the processing region 102A. The first and/or the second precursor fluid PF1, PF2 here is a liquid.

This method achieves a spatial atomic layer processing operation using at least one liquid precursor fluid PF1, PF2. The method may especially provide for the use of gaseous and liquid precursor fluids in a process.

Although the present invention has been described with reference to working examples, it is modifiable in various ways. From the disclosure given, those skilled in the art will not only understand the present invention and its attendant advantages, but will also find apparent the various modifications to the structures and methods disclosed. The Applicant seeks, therefore, to cover all such modifications as fall within the spirit and scope of the invention, as defined by the appended claims, and equivalents thereof.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Apparatus
101 Optical element
102 Surface
102A Surface region
103 Contamination
110 Sample holder
112 Temperature control unit
120 Processing head
121 First supply outlet (first outlet)
122 Second supply outlet (second outlet)
123 Cleaning arrangement
123A Inlet (suction nozzle)
123B Inlet (suction nozzle)
123C Inlet (suction nozzle)
123D Inlet (suction nozzle)
123E Inlet (suction nozzle)
123F Inlet (suction nozzle)
123X Purge fluid outlet
124 Outlet
125 Plasma generator
126 Measuring device
130 Movement unit
130A Movement unit
130B Movement unit
141 Reservoir
142A Conduit section
142B Conduit section
142C Conduit section
143 Pump
144 Pump
145 Separation apparatus
146 Temperature control unit
151 Reservoir
152A Conduit section
152B Conduit section
152C Conduit section
153 Pump
154 Pump
155 Separation apparatus
156 Temperature control unit
160 Housing
CR Chemical reaction (deposition/etching)
M1 Mirror
M2 Mirror
M3 Mirror
M4 Mirror
M5 Mirror
M6 Mirror
ML Monolayer
PF1 Precursor fluid
PF2 Precursor fluid
PF3 Precursor fluid
S1 Method step
S2 Method step
S3 Method step
S4 Method step
S5 Method step
SF1 Purge fluid
SF2 Purge fluid
SF3 Purge fluid
SF4 Purge fluid

What is claimed is:

1. An apparatus for processing of a surface of an optical element of a lithography apparatus in an atomic layer processing operation, comprising:
a sample holder configured to hold the optical element during the processing,
a processing head having a first supply outlet of a first precursor fluid to a processing region on the surface of the optical element, a cleaning arrangement for removal of excess first precursor fluid from the processing region, and a second supply outlet of a second precursor fluid to the processing region, wherein the first precursor fluid and the second precursor fluid are selected to perform an atomic layer deposition process or an atomic layer etching process as an atomic layer processing operation in the processing region, and wherein at least one of the first precursor fluid and the second precursor fluid is a liquid, and
a movement unit configured to move at least one of the processing head and the sample holder with the optical element relative to each other such that the first supply outlet, the cleaning arrangement and the second supply outlet are guided successively across the processing region,
wherein the respective precursor fluid is in a liquid state under process conditions under which the atomic layer processing operation is conducted and is contacted onto the surface of the optical element by the respective supply outlet in the liquid state.

2. The apparatus as claimed in claim 1, wherein the lithography apparatus is configured for operation with extreme ultraviolet (EUV) radiation.

3. The apparatus as claimed in claim 1, wherein the first precursor fluid and the second precursor fluid are liquids.

4. The apparatus as claimed in claim 1, wherein the optical element during the performing of the processing operation is disposed in an inert gas atmosphere having a pressure within a range from 0.01 atm-10 atm.

5. The apparatus as claimed in claim 4, wherein the pressure in the inert gas atmosphere is 0.1 atm-5 atm.

6. The apparatus as claimed in claim 1, wherein the cleaning arrangement comprises at least one outlet and/or inlet disposed between the first supply outlet and the second supply outlet along a path corresponding to the relative movement between the optical element and the processing head.

7. The apparatus as claimed in claim 1, wherein the cleaning arrangement comprises at least one inlet arranged for suction removal of the first precursor fluid or the second precursor fluid.

8. The apparatus as claimed in claim 7, wherein the at least one inlet opens into a pumped removal channel, and wherein a separation apparatus is disposed along the pumped removal channel and is configured to separate out and collect the pumped-off precursor fluid from the pumped-off fluid.

9. The apparatus as claimed in claim 1, wherein the cleaning arrangement comprises a plurality of inlets for suction removal of fluid and a plurality of purge fluid outlets for supply of respective purge fluid.

10. The apparatus as claimed in claim 9, wherein at least some of the purge fluid is a liquid.

11. The apparatus as claimed in claim 1, wherein the processing head comprises a temperature control device to control the temperature of the first and/or the second precursor fluid.

12. The apparatus as claimed in claim 1, wherein the first or the second precursor fluid is a gas and the processing head comprises a plasma generator configured to generate a plasma from the gaseous precursor fluid.

13. The apparatus as claimed in claim 1, further comprising a sample temperature control device for controlling the temperature of the optical element disposed in the sample holder.

14. The apparatus as claimed in claim 1, wherein the first precursor fluid is an acidic aqueous solution, and the second precursor fluid is an alkaline aqueous solution.

15. The apparatus as claimed in claim 14, wherein the first precursor fluid and/or the second precursor fluid additionally comprises an oxidizing agent.

16. The apparatus as claimed in claim 1, further comprising a measurement apparatus for detecting a distance between the processing head and the surface of the optical element, wherein the movement unit is configured to move the processing head and/or the optical element at a predetermined distance from each other.

17. The apparatus as claimed in claim 1, wherein the optical element has a surface with a curvature at least in sections, and an underside of the processing head which opposes the optical element during the processing operation has a shape matched to the curvature.

18. A method of processing of a surface of an optical element of a lithography apparatus, in an atomic layer processing operation, said method comprising:
arranging the optical element on a sample holder,
positioning a processing head opposite the surface of the optical element, such that a first supply outlet of the processing head is disposed opposite a processing region on the surface,
moving the processing head and/or the optical element such that the first supply outlet is moved across the processing region, wherein, during the movement, via the first supply outlet, a first precursor fluid is supplied to the processing region,
moving the processing head and/or the optical element, such that a cleaning arrangement of the processing head is moved across the processing region, wherein the cleaning arrangement is configured to remove excess first precursor fluid from the processing region, and
moving the processing head and/or the optical element such that a second supply outlet of the processing head is moved across the processing region, wherein, during the movement, via the second supply outlet, a second precursor fluid is supplied to the processing region,
wherein the first and the second precursor fluids are selected to perform an atomic layer deposition process or an atomic layer etching process in the processing region, and wherein the first and/or the second precursor fluid is a liquid, wherein the respective precursor fluid, which is a liquid, is in the liquid state under process conditions under which the atomic layer processing operation is conducted and is contacted onto the surface of the optical element by the respective supply outlet in the liquid state.

19. The method as claimed in claim 18, wherein the lithography apparatus operates with extreme ultraviolet (EUV) radiation.

20. A method of repairing a lithography apparatus, comprising:
removing an optical element from a beam path of the lithography apparatus, wherein the optical element has contamination and/or damage on a surface of incidence,
processing the optical element in a processing method as claimed in claim 18, and
installing the processed optical element in the lithography apparatus.

21. The method as claimed in claim 20, wherein the lithography apparatus is an EUV lithography apparatus.
